(19) United States
(12) Patent Application Publication
(10) Pub. No.: US 2016/0142044 A1
(43) Pub. Date: May 19, 2016

(54) SIGNAL PROCESSING DEVICE

(71) Applicant: DENSO CORPORATION, Kariya-city (JP)

(72) Inventor: Kazuki MIKAMO, Kariya-city (JP)

(21) Appl. No.: 14/882,736

(22) Filed: Oct. 14, 2015

(30) Foreign Application Priority Data
Nov. 17, 2014 (JP) 2014-232609

(51) Int. Cl. H03K 5/003; H03K 5/125; G01P 15/00

(52) U.S. Cl. CPC H03K 5/003; G01P 15/00; H03K 5/125

(57) ABSTRACT

A signal processing device includes: a signal processing circuit that processes an input signal, and outputs a signal corresponding to the input signal; an offset input device that inputs a diagnosis offset signal as an internal signal in a passage between an input side and an output side of the signal processing circuit; a self-diagnosis device that performs a self-diagnosis of the signal processing circuit based on a variation in the signal output from the signal processing circuit when the diagnosis offset signal input by the offset input device is varied by a predetermined amount; and an extraction device that removes a component of the diagnosis offset signal from the signal output from the signal processing circuit, and extracts only a signal corresponding to the input signal.

### CROSS REFERENCE TO RELATED APPLICATION

This application is based on Japanese Patent Application No. 2014-232609 filed on Nov. 17, 2014, the disclosure of which is incorporated herein by reference.

### TECHNICAL FIELD

The present disclosure relates to a signal processing device having a signal processing circuit that processes an input signal from a sensor unit for detecting, for example, a physical quantity, and outputs a signal corresponding to the input signal.

### BACKGROUND

For example, a capacitive acceleration sensor device mounted in an automobile airbag system includes a semiconductor acceleration sensor chip (sensor element), and a signal processing device mainly having a C/V conversion circuit that processes a detection signal from the sensor chip (for example, refer to JP-2009-75097 A (Patent Literature 1).

The acceleration sensor device is provided with a self-diagnosis function for diagnosing whether the acceleration sensor device per se operates normally, or not (a predetermined sensitivity is obtained, or abnormality such as foreign matter is present in the sensor chip). The self-diagnosis function forcedly supplies a self-diagnosis signal different from a carrier at the time of a normal acceleration detection to the acceleration sensor chip to perform a diagnosis according to whether a signal commensurate with the self-diagnosis signal is obtained, or not.

In the above Patent Literature 1, in order to realize the self-diagnosis function, there is a need to provide a process (phase) of the self-diagnosis separately from the normal acceleration detection time. For that reason, the self-diagnosis function needs to be executed at the time of starting the use of the sensor device (at the time of starting an engine), or to be performed with a changeover of the phase from the normal operation phase to the self-diagnosis process as occasion demands. In other words, up to now, the self-diagnosis can be performed only when the sensor unit is not used, and it is desirable that the self-diagnosis function can be always executed even during the use of the sensor unit (during acceleration detection).

### SUMMARY

It is an object of the present disclosure to provide a signal processing device having a signal processing circuit that processes an input signal from, for example, a sensor unit, which always executes a self-diagnosis function.

According to an example aspect of the present disclosure, a signal processing device includes: a signal processing circuit that processes an input signal, and outputs a signal corresponding to the input signal; an offset input device that inputs a diagnosis offset signal as an internal signal in a passage between an input side and an output side of the signal processing circuit; a self-diagnosis device that performs a self-diagnosis of the signal processing circuit based on a variation in the signal output from the signal processing circuit when the diagnosis offset signal input by the offset input device is varied by a predetermined amount; and an extraction device that removes a component of the diagnosis offset signal from the signal output from the signal processing circuit, and extracts only a signal corresponding to the input signal.

In the above signal processing device, when the offset input device forcibly inputs the diagnosis offset signal into the signal processing circuit, the signal in the signal processing circuit is varied with a variation amount corresponding to the diagnosis offset signal, according to a predetermined variation of the diagnosis offset signal. Thus, the self-diagnosis device monitors a variation of the signal with respect to the diagnosis offset signal, and the device can determine whether the signal processing circuit functions normally.

At the same time as the self-diagnosis, the extraction device extracts only the signal corresponding to the input signal from the signal output from the signal processing circuit by cancelling a variation of the diagnosis offset signal. Thus, the device always detects the physical quantity detected by the sensor unit. Thus, the signal processing device includes the signal processing circuit, the device always executes the self-diagnosis function without setting a phase for performing the self-diagnosis at a period other than a normal operation period.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a diagram schematically illustrating an electric configuration of a main portion of a semiconductor acceleration sensor device according to a first embodiment of the disclosure;

FIG. 2 is a timing chart illustrating an example of a waveform of a carrier, an offset input, and outputs of respective units;

FIG. 3A is a schematic top view of a sensor chip, and FIG. 3B is a vertically cross-sectional front view of the sensor chip;

FIG. 4 is a diagram illustrating a modification of a pattern of an offset input;

FIG. 5 is a diagram corresponding to FIG. 1 according to a second embodiment of the disclosure;

FIGS. 6A to 6C are diagrams illustrating a signal in each section;

FIG. 7 is a diagram corresponding to FIG. 1 according to a third embodiment of the disclosure; and

FIG. 8 is a timing chart illustrating an example of a waveform of a carrier, an offset input, and so on.

### DETAILED DESCRIPTION

### First Embodiment

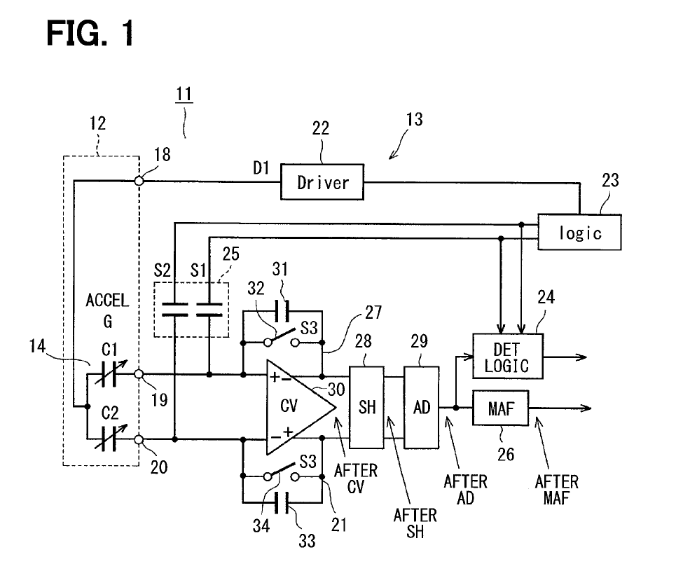

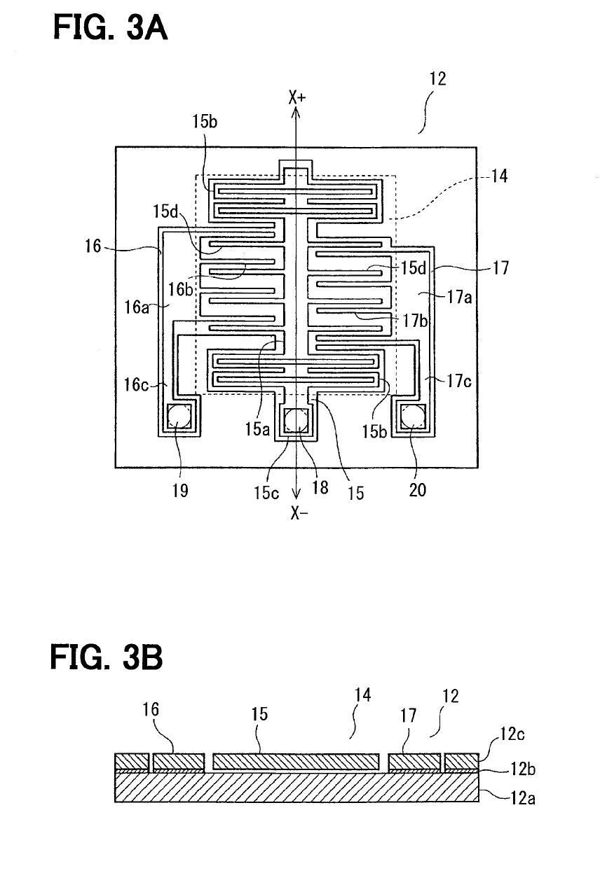

Hereinafter, a description will be given of a capacitive semiconductor acceleration sensor device according to a first embodiment of the disclosure with reference to FIGS. 1 to 3. FIG. 1 is a diagram schematically illustrating an electric configuration of a capacitive semiconductor acceleration sensor device 11, and FIGS. 3A and 3B are schematic views of a sensor chip 12 in the capacitive semiconductor acceleration sensor device 11. As illustrated in FIG. 1, the semiconductor acceleration sensor device 11 includes the sensor chip 12 as a sensor unit (sensor element), and a signal processing device 13 according to this embodiment.

First, a schematic configuration of the sensor chip 12 will be described. As illustrated in FIG. 3B, the sensor chip 12 has an acceleration detection unit 14 as a physical quantity detection unit which is located in a rectangular region of a center portion of the sensor chip 12. The acceleration detection unit 14 is formed, for example, in such a manner that a rectangular (square) SOI substrate where a single crystal silicon layer 12c is formed over a support substrate 12a made of silicon through an oxide film 12b is provided as a base, and grooves are produced in the single crystal silicon layer 12c of a surface of the SOI substrate through a micromachining technique.

In that case, the acceleration detection unit 14 has a detection axis (X-axis) in one direction, and detects an acceleration in an anteroposterior direction (X-axial direction) in FIG. 3A. The acceleration detection unit 14 includes a movable electrode part 15 that is displaced in the X-axial direction according to an action of acceleration, and a pair of first and second fixed electrode parts 16, 17 on left and right sides. In the acceleration detection unit 14, the movable electrode part 15 includes a weight part 15a, spring parts 15b, and an anchor part 15c. The weight part 15a extends in the center of the acceleration detection unit 14 in the anteroposterior direction. The spring parts 15b are provided on both ends of the weight part 15a in the anteroposterior direction, and each shaped into a slender rectangular frame in a lateral direction. The anchor part 15c is disposed in front of the front side spring part 15b in FIG. 3A. The movable electrode part 15 also includes multiple thin movable electrodes 15d extending from the weight part 15a toward the lateral direction in a so-called pectinate shape.

As illustrated in FIG. 3B, the movable electrode part 15 floats in a so-called cantilevered state where the oxide film 12b on a lower surface side of the sensor chip 12 is removed except for the anchor part 15c, and only the anchor part 15c is supported by the support substrate 12a. As illustrated in FIG. 1, an upper surface part of the anchor part 15c is equipped with an input terminal 18 formed of an electrode pad. As will be described later, a carrier D1 is input to the input terminal 18.

On the contrary, the first fixed electrode part 16 on the left side includes a rectangular base 16a, multiple fixed electrodes 16b extending from the rectangular base 16a to the right in a pectinate shape, and a fixed electrode wire part 16c extending forward from the base 16a. The respective fixed electrodes 16b are disposed to be adjacent to each other in parallel through a small gap immediately on a rear side of the respective movable electrodes 15d. As illustrated in FIG. 1, an upper surface of a front end of the fixed electrode wire part 16c is equipped with a first output terminal 19 formed of an electrode pad.

The second fixed electrode part 17 on the right side includes a rectangular base 17a, multiple fixed electrodes 17b extending from the rectangular base 17a to the left in a pectinate shape, and a fixed electrode wire part 17c extending forward from the base 17a. The respective fixed electrodes 17b are disposed to be adjacent to each other in parallel through a small gap immediately on a front side of the respective movable electrodes 15d. As illustrated in FIG. 1, an upper surface of a front end of the fixed electrode wire part 17c is equipped with a second output terminal 20 formed of an electrode pad.

As a result, capacitors C1 and C2 (refer to FIG. 1) having the movable electrode part 15 as a common electrode are formed between the movable electrode part 15 (movable electrodes 15d) and the first fixed electrode part 16 (fixed electrodes 16b) and between the movable electrode part 15 (movable electrodes 15d) and the second fixed electrode part 17 (fixed electrodes 17b), respectively. Capacitances of those capacitors C1 and C2 differentially change according to a displacement of the movable electrode part 15 caused by the action of acceleration in the X-axial direction, and therefore the acceleration can be extracted as a change in capacitance values.

Although not shown in detail, the sensor chip 12 has a so-called stack structure implemented on a circuit chip where the respective circuits of the signal processing device 13 are formed. The sensor chip 12 is housed in, for example, a package made of ceramic. The first and second output terminals (electrode pads 19 and 20) of the sensor chip 12 are connected to first and second input terminals (not illustrated) disposed in the signal processing device 13, respectively. The electric connections are performed by bonding wire connections or bump connections.

Then, the signal processing device 13 according to this embodiment will be described. As illustrated in FIG. 1, the signal processing device 13 has a signal processing circuit 21 for processing the signal from the sensor chip 12. In addition, the signal processing device 13 includes a carrier signal input circuit 22, a control logic circuit 23, a determination logic circuit 24, a diagnosis offset input circuit 25, and a moving average filter circuit (MAF) 26. The control logic circuit 23 and the determination logic circuit 24 each mainly include a computer, and perform controls and determinations to be described later with a software configuration of the computer.

The signal processing circuit 21 includes a fully differential C/V conversion circuit 27 that converts a capacitance change into a voltage change, a sample and hold (S/H) circuit 28 that samples and holds a voltage signal output from the C/V conversion circuit 27 at a predetermined timing, and an A/D conversion circuit 29 that converts a signal output from the sample and hold circuit 28 into a digital signal. The output signal processed in the signal processing circuit 21 is output from the A/D conversion circuit 29.

The C/V conversion circuit 27 includes a fully differential amplifier 30 having two non-inverting and inverting input terminals and two first and second output terminals, a capacitor 31 and a first switch 32 which are connected in parallel to each other between the non-inverting input terminal of the fully differential amplifier 30 and the first output terminal on a negative side, and a capacitor 33 and a second switch 34 which are connected in parallel to each other between the inverting input terminal of the fully differential amplifier 30 and the second output terminal on a positive side. The first output terminal 19 of the sensor chip 12 is connected to the non-inverting input terminal of the fully differential amplifier 30, and the second output terminal 20 of the sensor chip 12 is connected to the inverting input terminal of the fully differential amplifier 30.

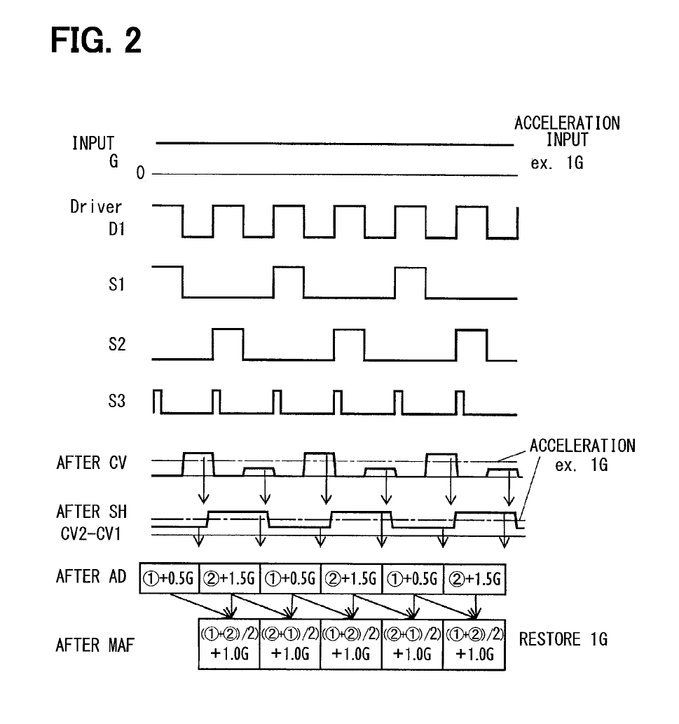

The carrier signal input circuit 22 generates the carrier D1, and inputs the carrier D1 to the movable electrode part 15 (input terminal 18) of the sensor chip 12 on the basis of a command from the control logic circuit 23. As illustrated in FIG. 2, the carrier D1 amplitudes between a predetermined voltage (for example, 5V equal to a power source voltage) and 0V, and is formed into a pulse shape (rectangular waveform) having a frequency of, for example, 120 kHz. In this situation, the carrier D1 is always supplied to the movable electrode part 15 during the operation of the acceleration sensor device 11.

The diagnosis offset input circuit 25 inputs a diagnosis offset to any internal signal of the signal processing circuit 21 on the basis of the command from the control logic circuit 23. Therefore, the diagnosis offset input circuit 25 functions as offset input device. In this embodiment, the output signal is input to an input side of the C/V conversion circuit 27 (fully differential amplifier 30). In detail, as will be described in the description of the operation later, the diagnosis offset input circuit 25 inputs offset signals S1 and S2 to the non-inverting input terminal and the inverting input terminal of the fully differential amplifier 30, respectively. Those offset signals S1 and S2 have magnitudes corresponding to +0.5 G and −0.5 G, for example, in acceleration conversion, respectively.

In this situation, as illustrated in FIG. 2, the diagnosis offset input circuit 25 alternately inputs the positive offset signal S1 and the negative offset signal S2 to the positive side and the negative side with a substantially equal amplitude in synchronization with the timing of sampling of the signal from the signal processing circuit 21 (carrier D1 at timing of Hi). In other words, the positive and negative offsets are input with a deflection width corresponding to 1 G (predetermined amount) (varied with an equal amplitude). As illustrated in FIG. 1, an output signal from the signal processing circuit 21 (A/D conversion circuit 29) is input to the determination logic circuit 24, and a self-diagnosis (determination of whether abnormality is present, or not) is performed on the basis of a variation in the output signal.

In addition, an output signal from the signal processing circuit 21 (A/D conversion circuit 29) is input to the moving average filter circuit 26. The moving average filter circuit 26 calculates an average value [{X(n)+X(n−1)}/2] between a present signal X(n) and a last signal X(n−1) from the A/D conversion circuit 29. Through the calculation in the moving average filter circuit 26, the offset signals S1 and S2 (two offset inputs) are canceled, and only a signal (acceleration detection signal) corresponding to the input signal to the signal processing circuit 21, that is, corresponding to the detection signal of the sensor chip 12 is extracted.

Therefore, the determination logic circuit 24 functions as self-diagnosis device, and the moving average filter circuit 26 functions as extraction device. The first and second switches 32 and 34 of the C/V conversion circuit 27 are intended for reset of the capacitors 31 and 33, and as illustrated in FIG. 2, are turned on at an appropriate timing (rising timing of the pulse of the carrier D1) by the control logic circuit 23.

Then, the operation of the above configuration will be described also with reference to FIG. 2. FIG. 2 illustrates a relationship of a waveform of the carrier D1 input to the movable electrode part 15 of the sensor chip 12, and the offset signals S1 and S2 input to the input side of the C/V conversion circuit 27 (fully differential amplifier 30) in the signal processing circuit 21 by the diagnosis offset input circuit 25, in the operation of the semiconductor acceleration sensor device 11. FIG. 2 illustrates an example of an output signal from the C/V conversion circuit 27, an output signal from the sample and hold circuit 28, an output signal from the A/D conversion circuit 29, and an output signal from the moving average filter circuit 26 together. FIG. 2 illustrates a state in which no abnormality is present in the sensor chip 12 and the signal processing device 13, and the acceleration of, for example, 1 G acts on the sensor chip 12 and the signal processing device 13.

As described above, in the operation of the semiconductor acceleration sensor device 11, the offset signal S1 (+0.5 G equivalent) and the offset signal S2 (−0.5 G equivalent) are always alternately input in synchronization with the carrier D1. When it is assumed that the output signal from the A/D conversion circuit 29 when receiving the offset signal S1 is X1 (number 1 in each white circle in FIG. 2), and the output signal from the A/D conversion circuit 29 when receiving the offset signal S2 is X2 (number 2 in each white circle in FIG. 2), the signal X1 and the signal X2 are alternately output from the A/D conversion circuit 29.

Those output signals X1 and X2 are input to the determination logic circuit 24 to perform the abnormality diagnosis. In the case of normal (no abnormality), the magnitude of the signal X1 corresponds to +0.5 G, the magnitude of the signal X2 corresponds to +1.5 G, and those signals are alternately output. On the contrary, when the abnormality is present in the signal processing circuit 21 or the sensor chip 12, since the magnitude of the amplitude between the signal X1 and the signal X2, or an average value between the signal X1 and the signal X2 is changed, it can be determined that the abnormality occurs in the signal processing circuit 21 or the sensor chip 12.

For example, when abnormality that the sensitivity is too high is present, a value (X2−X1) of the amplitude between the signal X1 and the signal X2 is larger than the 1 G equivalent. When abnormality that the sensitivity is too low is present, the value (X2−X1) of the amplitude between the signal X1 and the signal X2 is smaller than the 1 G equivalent. When the abnormality of polarity inversion is present, the value of the amplitude between the signal X1 and the signal X2 is smaller than the 1 G equivalent. If the offset abnormality is present, the average value {(X1+X2)}/2} between the signal X1 and the signal X2 is deviated from the 1 G equivalent. In this way, the abnormality is determined by the determination logic circuit 24 according to the output signals X1 and X2.

The output signals X1 and X2 from the A/D conversion circuit 29 are input to the moving average filter circuit 26, and an average of the output signals X1 and X2 and the last output signal is taken twice. In other words, when the signal X2 is input to the moving average filter circuit 26, an average {(X1+X2)/2} between the input signal X2 and the last signal X1 is obtained. When the signal X1 is input to the moving average filter circuit 26, an average {(X2+X1)/2} between the input signal X1 and the last signal X2 is obtained. As a result, through the moving average filter circuit 26, the offset signals S1 and S2 (two offset inputs) are canceled, and only a signal (for example, 1.0 G equivalent) corresponding to the input signal to the signal processing circuit 21, that is, corresponding to the detection signal of the sensor chip 12 is extracted.

As described above, according to the signal processing device 13 of this embodiment, the diagnosis offset signals S1 and S2 can be forcedly input to the C/V conversion circuit 27 in the signal processing circuit 21 by the diagnosis offset input circuit 25. The output signal from the signal processing circuit 21 (A/D conversion circuit 29) is varied with the variation commensurate with the offset according to a predetermined amount of variation of the offset input. As a result, the determination logic circuit 24 monitors the output variation to the offset input, thereby being capable of diagnosing whether the signal processing circuit 21 operates normally, or not.

At the same time as the above self-diagnosis, the variation in the offset input is canceled by the moving average filter circuit 26 to enable only a portion corresponding to the input signal (acceleration detection signal) to be extracted from the output signal from the signal processing circuit 21 (A/D conversion circuit 29), and the acceleration detected by the sensor chip 12 can be always detected. Therefore, this embodiment is provided with the signal processing circuit 21, and obtains such excellent advantages that the self-diagnosis function can be always executed unlike the conventional art that provides the self-diagnosis phase at a time other than the normal operation.

In the above first embodiment, the offset signal S1 on the positive side and the offset signal S2 on the negative side are alternately input by the diagnosis offset input circuit 25 in synchronization with the carrier D1. Alternatively, the disclosure can employ another pattern of the input (variation) of the offset signals. In other words, as a modification of the pattern of the offset signal input, the input and input stop (offset is 0) of the offset signal S1 on the positive side, and the input and input stop (offset is 0) of the offset signal S2 on the negative side can be repeated in order in synchronization with the carrier D1 (at timing when the carrier D1 is Hi).

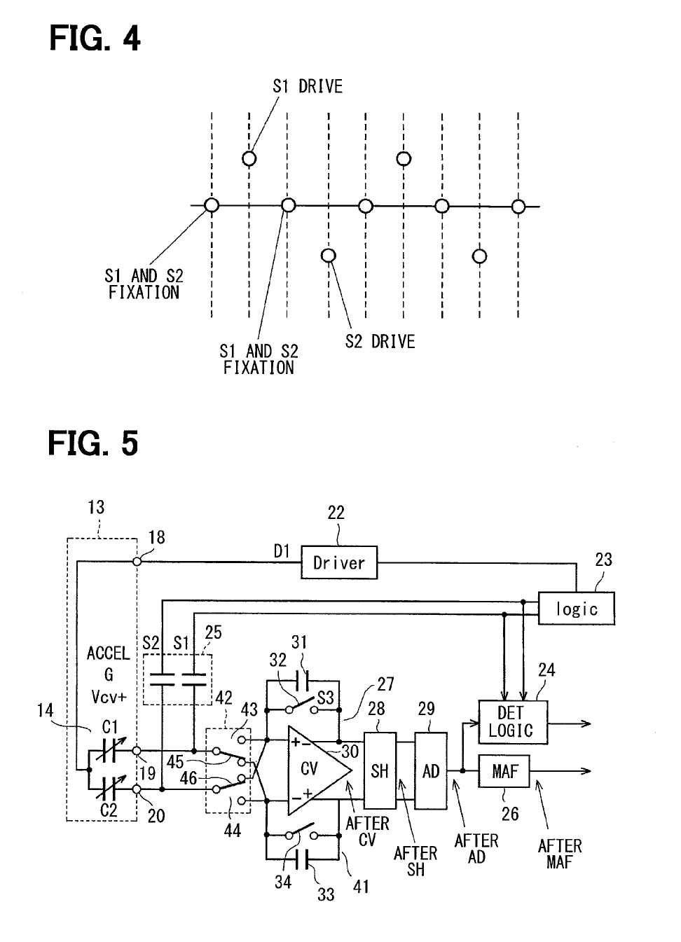

In this event, as illustrated in FIG. 4, in the normal case, the output signal from the signal processing circuit 21 (A/D conversion circuit 29) repeats 1.5 G equivalent, 1 G equivalent, 0.5 G equivalent, and 1 G equivalent in correspondence with the input pattern of the offset signal. Similarly, in this case, when the abnormality is present in the signal processing circuit 21 or the sensor chip 12, since the magnitude of the amplitude of the output signal from the A/D conversion circuit 29, or an average value of the magnitude is changed, it can be determined in the determination logic circuit 24 that the abnormality occurs in the signal processing circuit 21 or the sensor chip 12. The offset abnormality can be determined according to the output signal from the A/D conversion circuit 29 at the time of stopping the offset input regardless of whether a failure is present in the signal processing device 13, or not.

In the moving average filter circuit 26, an average value [{X(n)+2*X(n−1)+X(n−2) }/4] is calculated according to the present signal X(n), the last signal X(n−1), and a second last signal X(n−2) from the A/D conversion circuit 29 so that the signals at the time of inputting the positive and negative offset signal are input one by one. Alternatively, an average value [{X(n)+X(n−1)+X(n−2)+X(n−3)}/4] is calculated. As a result, the acceleration detected by the sensor chip 12 can be always detected.

### Second Embodiment

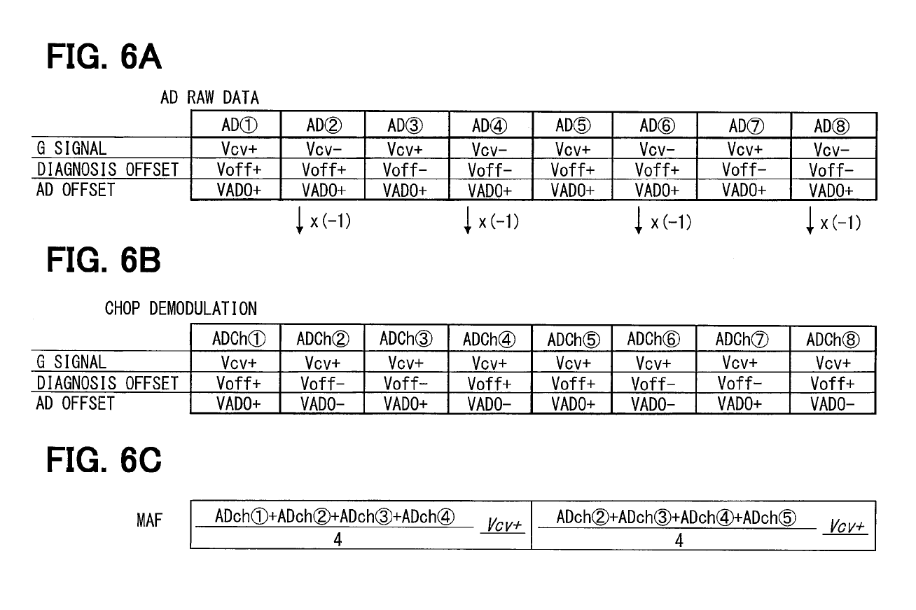

FIGS. 5 and 6 illustrate a second embodiment of the disclosure. The second embodiment is different from the above first embodiment in the configuration of a signal processing circuit 41. In other words, in the signal processing circuit 41 according to this embodiment, a chopping circuit 42 is disposed on an input side (subsequent stage to an input portion of the offset signals S1 and S2 by the diagnosis offset input circuit 25) of the totally differential C/V conversion circuit 27.

The chopping circuit 42 includes a third switch 43, a fourth switch 44, a fifth switch 45, and a sixth switch 46. The third switch 43 is inserted between a first output terminal 19 and a non-inverting input terminal of a fully differential amplifier 30. The fourth switch 44 is inserted between a second output terminal 20 and an inverting input terminal of the fully differential amplifier 30. The fifth switch 45 is inserted between the first output terminal 19 and the inverting input terminal of the fully differential amplifier 30. The sixth switch 46 is inserted between the second output terminal 20 and the non-inverting input terminal of the fully differential amplifier 30.

The chopping circuit 42, that is, the third to sixth switches 43 to 46 are controlled in on/off operation by the control logic circuit 23. In this situation, a state in which the third switch 43 and the fourth switch 44 are on, and the fifth switch 45 and the sixth switch 46 are off in the chopping circuit 42 is called “forward state”. In the forward state, an offset signal S1 is input to the non-inverting input terminal of the fully differential amplifier 30, and an offset signal S2 is input to the inverting input terminal of the fully differential amplifier 30.

On the contrary, a state in which the third switch 43 and the fourth switch 44 are off, and the fifth switch 45 and the sixth switch 46 are on in the chopping circuit 42 is called “inversion state”. In the inversion state, the offset signal S1 is input to the inverting input terminal of the fully differential amplifier 30, and the offset signal S2 is input to the non-inverting input terminal of the fully differential amplifier 30.

In this case, the offset signal S1 on the positive side, the offset signal S1 on the positive side, the offset signal S2 on the negative side, and the offset signal S2 on the negative side are repetitively input to the positive side and the negative side with a substantially equal amplitude in the stated order from the diagnosis offset input circuit 25 in synchronization with a carrier D1 (at a timing when the carrier D1 is Hi). The forward state, the inversion state, the forward state, and the inversion state are alternately switched by the chopping circuit 42 at a timing synchronous with the above input.

FIGS. 6A to 6C illustrate a signal (Vcv+) of an acceleration (G) from a sensor chip 12, an offset signal (positive offset input is Voff+, negative offset input is Voff−) input from the diagnosis offset input circuit 25, and an output signal (VADO+ in a case including the positive offset input, and VADO− in a case including the negative offset input) from an A/D conversion circuit 29, in eight sections (eight cycles of the carrier D1) of AD1 to AD8. FIG. 6A illustrates data that remains chopped, and FIG. 6B illustrates data when chopping is demodulated (ADCh1 to ADCh8). FIG. 6C illustrates an extracted signal by a moving average filter circuit 26.

The section AD1 shows an appearance in which the offset signal S1 on the positive side is input to the chopping circuit 42, and the chopping circuit 42 is in the forward state, and the section AD2 shows an appearance in which the offset signal S1 on the positive side is input to the chopping circuit 42, and the chopping circuit 42 is in the inversion state. The section AD3 shows an appearance in which the offset signal S2 on the negative side is input to the chopping circuit 42, and the chopping circuit 42 is in the forward state, and the section AD4 shows an appearance in which the offset signal S2 on the negative side is input to the chopping circuit 42, and the chopping circuit 42 is in the inversion state. A pattern of those sections AD1 to AD4 is also repeated in the sections AD5 to AD8.

As is apparent from FIG. 6, similarly, in a configuration where the chopping circuit 42 described above is provided, even if the offset input from the diagnosis offset input circuit 25 is performed in the order of positive, positive, negative, and negative to implement the signal inversion by the chopping circuit 42, the output signal from the A/D conversion circuit 29 which has been subjected to the demodulation of the chopping is alternately deflected to the positive and negative. As a result, the abnormality determination (self-diagnosis) can be performed by the determination logic circuit 24. In the moving average filter circuit 26, with the calculation of an average value of four output signals, a variation in the offset input is canceled, only a portion corresponding to an acceleration detection signal of the sensor chip 12 can be extracted to always detect the acceleration.

Therefore, similarly, the second embodiment is provided with the signal processing circuit 41, and obtains such excellent advantages that the self-diagnosis function can be always executed unlike the conventional art that provides the self-diagnosis phase at a time other than the normal operation. In the second embodiment, the chopping circuit 42 is disposed in the subsequent stage to the input portion of the offset signals S1 and S2 by the diagnosis offset input circuit 25. Alternatively, the chopping circuit 42 may be disposed on an output side of the C/V conversion circuit 27 or on an output side of the sample and hold circuit 28, and can be implemented under the same control.

### Third Embodiment, and Other Embodiments

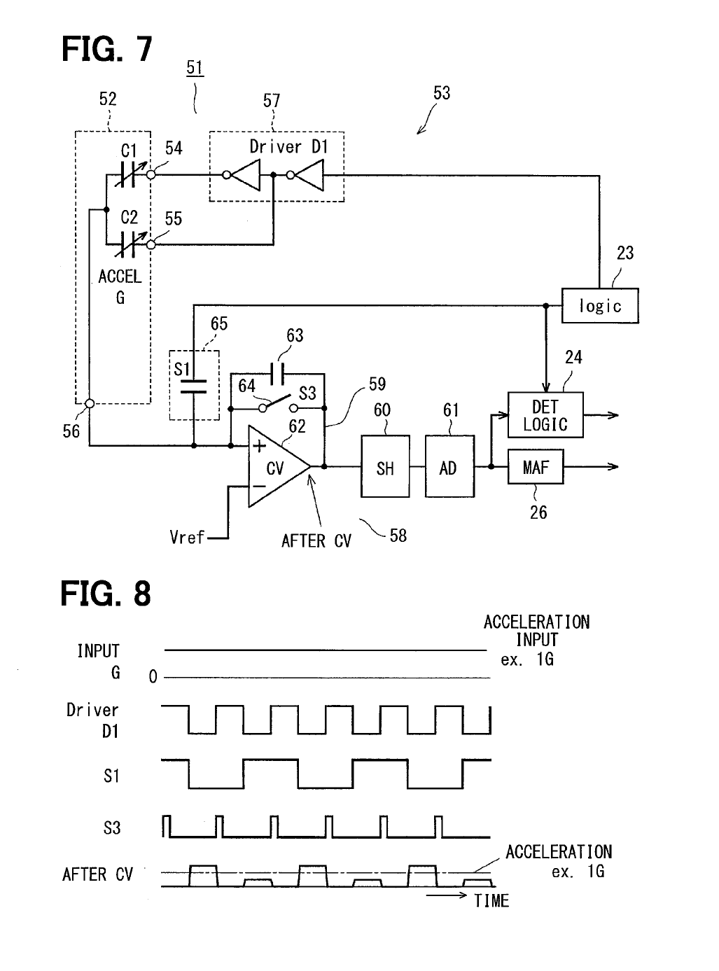

Subsequently, a third embodiment of the disclosure will be described with reference to FIGS. 7 and 8. FIG. 7 schematically illustrates an electric configuration of a main portion of a semiconductor acceleration sensor device 51 according to this embodiment. The semiconductor acceleration sensor device 51 includes a sensor chip 52 as a sensor unit, and a signal processing device 53. In the semiconductor acceleration sensor device 51, the sensor chip 52 includes a movable electrode part 15, and a pair of fixed electrode parts 16 and 17, and capacitors C1 and C2 are configured by those components.

The sensor chip 52 is equipped with first and second input terminals 54 and 55 connected to the fixed electrode parts 16 and 17, respectively, and an output terminal 56 connected to the movable electrode part 15. The input terminals 54 and 55 are connected with a carrier input circuit 57, and pulsed carriers whose potential has an amplitude between Vp (for example, 5V) and Vm (for example, 0V), and are opposite in phase to each other are supplied to the input terminals 54 and 55. The output terminal 56 is connected to a signal processing circuit 58 of the signal processing device 53.

The signal processing circuit 58 includes a single end C/V conversion circuit 59, a sample and hold (S/H) circuit 60, and an A/D conversion circuit 61. The C/V conversion circuit 59 includes an arithmetic amplifier 62, and a feedback capacitor 63 and a switch 64 which are connected in parallel to each other between a non-inverting input terminal and an output terminal of the arithmetic amplifier 62. The output terminal 56 is connected to the non-inverting input terminal of the arithmetic amplifier 62. A predetermined (DC) voltage signal, for example, an intermediate voltage Vref of a carrier is input to an inverting input terminal of the arithmetic amplifier 62.

In addition, the signal processing device 53 includes a control logic circuit 23, a determination logic circuit 24, and a moving average filter circuit (MAF) 26. The signal processing device 53 also includes a diagnosis offset input circuit 65. The diagnosis offset input circuit 65 inputs an offset signal S1 (for example, a signal corresponding to +0.5 G, for example, in acceleration conversion) to an input side of the C/V conversion circuit 59 (arithmetic amplifier 62) on the basis of a command from the control logic circuit 23. In this case, as illustrated in FIG. 8, the diagnosis offset input circuit 65 alternately performs an input and an input stop (offset is 0) of the offset signal S1 for each one cycle of Hi and Lo of the carrier D1 in synchronization with a timing of sampling of a signal from the signal processing circuit 58.

As in the above first embodiment (FIG. 2), FIG. 8 illustrates a signal of each component when no abnormality is present in the sensor chip 52 and the signal processing device 53, and the acceleration of, for example, 1 G acts on the sensor chip 52 and the signal processing device 53. The waveform of the offset signal S1 is different from that in the first embodiment, but the output signal from the C/V conversion circuit 59 is equal to that in the first embodiment. As a result, although not shown, an output signal from the sample and hold circuit 60, an output signal from the A/D conversion circuit 61, and an output signal from the moving average filter circuit 26 are equal to those shown in FIG. 2.

As a result, similarly, in this embodiment, the determination logic circuit 24 monitors the output variation to the offset input, thereby being capable of diagnosing whether the signal processing circuit 58 operates normally, or not. At the same time as the above self-diagnosis, the variation in the offset input is canceled by the moving average filter circuit 26 to enable only a portion corresponding to the input signal (acceleration detection signal) to be extracted from the output signal from the signal processing circuit 58 (A/D conversion circuit 61), and the acceleration detected by the sensor chip 52 can be always detected. Therefore, similarly, the third embodiment is provided with the signal processing circuit 58, and can obtain such an advantageous effect that the self-diagnosis function can be always executed.

Although not described in the above respective embodiments, the signal processing circuit may provide a zero point adjustment mechanism that adjusts an output (zero point) of the sensor unit in a state where a physical quantity does not act on the sensor unit. In the case of providing the zero point adjustment mechanism as described above, the offset input device (diagnosis offset input circuit) can also function as the zero point adjustment mechanism, and the configuration can be more simplified. In the above respective embodiments, the moving average filter is employed as the extraction device. Alternatively, the extraction device can be configured by the combination of a low pass filter or a band pass filter with the moving average filter.

In the above respective embodiments, the offset signal is input to the input side of the C/V conversion circuit by the diagnosis offset input circuit. Alternatively, the output signal may be input to the input side of the sample and hold circuit, or the input side of the A/D conversion circuit. In addition, in the above respective embodiments, the disclosure is applied to the semiconductor acceleration sensor device. Alternatively, the disclosure can be applied to another capacitive semiconductor sensor device such as a yaw rate sensor. Further, the disclosure can be applied to the general signal processing devices. The signal processing circuit may include no C/V conversion circuit, and the signal waveforms in the respective components merely show an example, and the disclosure can be implemented with an appropriate change without departing from the spirit of the disclosure.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A signal processing device comprising:
a signal processing circuit that processes an input signal, and outputs a signal corresponding to the input signal;
an offset input device that inputs a diagnosis offset signal as an internal signal in a passage between an input side and an output side of the signal processing circuit;
a self-diagnosis device that performs a self-diagnosis of the signal processing circuit based on a variation in the signal output from the signal processing circuit when the diagnosis offset signal input by the offset input device is varied by a predetermined amount; and
an extraction device that removes a component of the diagnosis offset signal from the signal output from the signal processing circuit, and extracts only a signal corresponding to the input signal.

2. The signal processing device according to claim 1, further comprising:
a sensor unit that detects a physical quantity, wherein:
a detection signal corresponding to the physical quantity detected by the sensor unit is input into the signal processing circuit as the input signal.

3. The signal processing device according to claim 2, wherein:
the sensor unit outputs a change in the physical quantity as a change in capacitance; and
the signal processing circuit includes a capacitance-voltage conversion circuit that converts the change in the capacitance into a voltage signal, and a sample and hold circuit that samples and holds the voltage signal output from the capacitance-voltage conversion circuit at a predetermined timing.

4. The signal processing device according to claim 3, wherein:
the signal processing circuit includes an analog-digital conversion circuit that converts a signal output from the sample and hold circuit into a digital signal.

5. The signal processing device according to claim 3, wherein:
the offset input device inputs the diagnosis offset signal into an input side of the capacitance-voltage conversion circuit.

6. The signal processing device according to claim 3, wherein:
the offset input device inputs the diagnosis offset signal into an input side of the sample and hold circuit.

7. The signal processing device according to claim 4, wherein:
the offset input device inputs the diagnosis offset signal into an input side of the analog-digital conversion circuit.

8. The signal processing device according to claim 3, wherein:
the capacitance-voltage conversion circuit is a differential type capacitance-voltage conversion circuit; and
the offset input device inputs the diagnosis offset signal as the input signal into two input sides of the capacitance-voltage conversion circuit.

9. The signal processing device according to claim 8, wherein:
the offset input device regularly inputs the diagnosis offset signal with a substantially equal amplitude into a positive input side and a negative input side in synchronization with a sampling timing of the signal.

10. The signal processing device according to claim 1, wherein:
the extraction device includes a moving average filter.

11. The signal processing device according to claim 10, wherein:
the extraction device includes a combination of the moving average filter
and one of a low pass filter and a band pass filter.
